(19) United States
(12) Patent Application Publication
(10) Pub. No.: US 2005/0006790 A1
(43) Pub. Date: Jan. 13, 2005

(54) [BONDING PAD STRUCTURE]

(76) Inventor: Min-Lung Huang, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,400

(22) Filed: Jul. 8, 2004

(30) Foreign Application Priority Data
Jul. 8, 2003 (TW) 92118568

(51) Int. Cl. H01L 21/44; H01L 23/48; H01L 23/52; H01L 29/40

(52) U.S. Cl. 257/779

(57) ABSTRACT

A bonding pad structure is suitable for a chip to improve conventional current density crowding at the bonding location between a bonding pad and an UBM layer, at which a current can not smoothly flow through due to the turning angle of the bonding location is overlarge. Therefore, an improvement structure of the bonding pad is formed by including a protruding pad on the top surface of the bonding pad. The turning angle of side profile of the protruding pad connected to the top surface of the bonding pad is less than 90 degrees, so as to smooth the turning angle when the current passes through.

### CROSS REFERENCE TO RELATED APPLICATIONS

This application claims the priority benefit of Taiwan application serial no. 92118568, filed Jul. 8, 2003.

### BACKGROUND OF INVENTION

1. Field of Invention

The present invention relates to bonding pad structure. More particularly, the present invention relates to an improved structure of the bonding pad.

2. Description of Related Art

In the semiconductor fabrication, the production of integrated circuit (IC) is basically divided into three stages: wafer fabrication, IC fabrication, and IC package. Wherein, a die is accomplished after the steps of wafer fabrication, circuit design, circuit fabrication, and wafer cutting. For each accomplished die, cutting from the wafer, after the bonding pads of the die are electrically coupled to external signal lines, the die is packaged. The purpose of packaging the die is to prevent the humidity, thermal energy, and noise from affecting on the die. Also and, the package also provides a way for allowing the die to be electrically coupled to the external circuit, such as the printed circuit board or other packaging substrate. As a result, packaging process on the IC is accomplished.

In order to couple the foregoing chip and the substrate being used for package, wire and/or conductive bump are used as the medium for coupling. A flip chip interconnect technology can be used, wherein the bonding pads of the chip are formed by conductive bumps and arranged in an array. And then, after the chip is flipped, the conductive bumps of the chip are respectively connected to the contacts of the packaging substrate, so that the chip can be electrically connected to the packaging substrate via the conductive bumps, and then are electrically coupled to the external signal terminals via the interconnection circuit and the surface contacts of the packaging substrate.

Referring to FIG. 1, it is a cross-sectional view, schematically illustrating a conventional bonding pad structure. Each chip 100 cut from the wafer has several bonding pad 100, in which only one bonding pad is shown, for use as connection points of the chip 100 to connect to the external signals. The bonding pad 110, for example, is on the active surface 102 of the chip 100, being arranged in a planar array, so as to increase the number of contact points. In addition, in order to prevent the outmost circuit pattern (not show) of the chip 100 from being damaged due to contamination and mechanical effect, the active surface 102 of the chip 100 is formed with a passivation layer 104. This passivation layer 104 is formed by, for example, depositing an organic protection material or an inorganic protection material, for covering the active surface 102 of the chip 100. Also and, openings 106 are formed above the top surface 112 of the bonding pad 104, which is not covered by the passivation layer 104, so as to be used as the connection via used by the subsequent process for forming the bumps.

Also referring to FIG. 1, an under bump metallurgic (UBM) layer 120 and a conductive bump 122 are formed on the bonding pad 110 by the bump fabrication process, so as to serve as the conductive structure for electrically and mechanically coupling the chip 100 to the packaging substrate (not shown). Wherein, the UBM layer 120 is disposed between the top surface 112 of the bonding pad 110 and the bottom surface of the conductive bump 122, so as to improve the coupling effect between the bonding pad 110 and the conductive bump 122. In general, the UBM layer 120 is a composite metallic layer composed from an adhesive layer, a barrier layer, and a wetting layer of tin with lead. The conductive bump 122 is formed by, for example, tin/lead bump, which can be formed as a ball-like bump by reflow process.

It should be noted that since the UBM layer 120 is formed on the top surface 120 of the bonding par 110 and the peripheral surface of the opening 106 by a manner of step coverage, the bonding location between the portion of surface of UBM layer 120 near to the sidewall of the opening 106 and the top surface 120 would have a turning angle 108, which angleθ₁ is greater than 90 degrees. However, when the operation speed of the chip 100 increases, it is often that a large amount of current flows through the bonding pad 110 and also passes through the turning angle 108. Due to the quantity of the turning angle 108 is overlarge, it causes an overcrowding when the current flowing through this turning angle 108. In other words, the current density at the this region of turning angle increases, and it further causes an electromigration phenomenon on the turning region due to metallic atoms being diffused. As a result, the metallic atoms of the UBM layer 120 under the current effect for a long period will loss due to electromigration, and an open circuit then occurs between the bonding pad 110 and the UBM layer 120, affecting the lifetime of the chip 100.

### SUMMARY OF INVENTION

The invention provides a bonding pad structure, so as to allow the current to have a smoother path when current flows over the turning angle region, so as to reduce the phenomenon of overcrowding current.

To achieve at least the foregoing objective, the invention provides a bonding pad structure, suitable for use in a chip, to reduce the electromigration phenomenon due to overlarge turning angle when the current flows through the bonding location between the bonding pad and the UBM layer. The improved structure of the bonding pad includes a protruding pad disposed on the top surface of the bonding pad. The bonding location between the side profile of the protruding pad and the top surface of the bonding pad has a turning angle. This turning angle is substantially less than 90 degrees, so as to smooth the turning angle for the current flowing through this turning angle region.

For achieving the foregoing objective, the invention provides a conductive structure on the bonding pad, suitable for use in a chip, and the chip having at least one bonding pad. The conductive structure on the bonding pad is mainly formed from a protruding pad, an UBM layer, and a conductive bump, wherein the protruding pad is located on the bonding pad and protrudes from the top surface of the bonding pad. The bonding location between the side profile of the protruding pad and the top surface of the bonding pad has a turning angle, which is less than 90 degrees. In addition, the UBM layer is disposed between the protruding pad and the conductive bump, so as allow the bottom portion of the conductive bump to be electrically coupled to the top surface of the UBM layer, and is formed together with the bonding pad as an integrated conductive structure.

According to the embodiment of the invention, the side profile of the foregoing protruding pad can be, for example, a curving surface or an arc surface, and is protruding from top surface of the bonding pad. Therefore, when the current flows through the foregoing turning angle, since the turning angle is less than 90 degrees, it does not cause the conventional phenomenon of overcrowding current at the turning angle due to the conventional abruptly turning current path. As a result, the invention can reduce possibility of opening circuit between the bonding pad and the UBM layer due to electromigration, and further improve the lifetime of the chip.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view, schematically illustrating a conventional bonding pad structure.

FIG. 2 is a cross-sectional view, schematically illustrating a bonding pad structure, according to an embodiment of the invention.

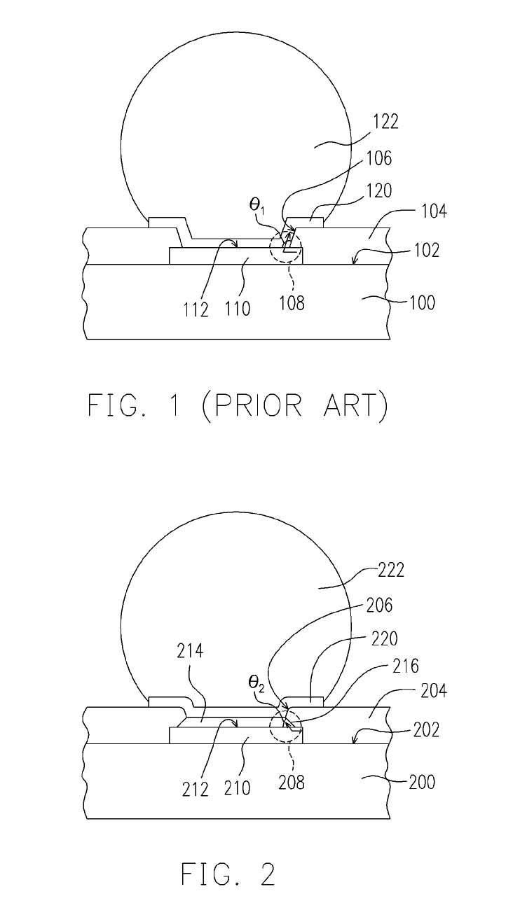

### DETAILED DESCRIPTION

Referring to FIG. 2, it is a cross-sectional view, schematically illustrating a bonding pad structure, according to an embodiment of the invention. In FIG. 2, The improved structure of the bonding pad is forming a protruding pad 214 on the top surface of the bonding pad 210. The bonding location between the side profile of the protruding pad 214 and the top surface 212 of the bonding pad 210 has a turning angle 208, and the turning angle 208 is the angleθ₂ less than 90 degrees, so as to reduce occurrence of the electromigration phenomenon due to the overlarge turning angleθ₁ when the current flow through the conventional bonding location between the bonding pad 110 and the UBM layer 120. In addition, in order to prevent the outmost circuit pattern layer (not shown) of the chip from being damaged due to external contamination and the mechanical effect, the active surface 202 of the chip 200 is formed with a passivation layer 204. This passivation layer 204 is formed by, for example, depositing an organic protection material or an inorganic protection material, for covering the active surface 202 of the chip 200. Also and, the passivation layer 204 covers a portion of the surface of the bonding pad 210 and the surface of the transmission 214. The other portion not being covered by the passivation layer 204 form an opening 206 above the surface 212 of the bonding pad 210, so as to serve as the connection via being used for the subsequent fabrication process for forming the bumps and bonding.

In addition, it can be seen from the side profile of the protruding pad 214 that the central region is protruding like the eminence, and the central region is smoothly descending toward the side, and then the side profile connect to the top surface 212 of the bonding pad 210. The material to form the protruding pad 214 includes alloy of copper, aluminum or gold, and the side profile of the protruding pad 214 can be a curving surface or an arc surface. Even though it still has the turning angle 208, the angle variance can be controlled to be small without causing the abruptly turning angle. As a result, when a large amount of current flows through the foregoing turning angle 208, the turning angleθ₂ can be less than 90 degrees or even less than 45 degrees or even smaller. Therefore, it does not cause the current to flow through a conventional path with abrupt turn, and then cause the conventional phenomenon of crowding current when a large amount of current flowing through the turning angleθ₁. The possibility of open circuit between the conventional bonding pad 110 and the UBM layer 120 due to the electromigration can be reduced, and the chip lifetime can thereby be prolonged.

Referring to FIG. 2, in the embodiment, an UBM layer 220 and a conductive bump 222 can be formed on the protruding pad 214 by a bump fabrication process, so as to serves as the conductive structure of the chip 200 to electrically and mechanically coupled to a packaging substrate (not shown). Wherein, the UBM 220 is disposed between the top surface of the protruding pad 214 and the bottom surface of the conductive bump 222, so as to improve the coupling quality between the protruding pad 214 and the conductive bump 222. Further still, the UBM 220 is, for example, formed by a composite metallic layer from an adhesive layer, a barrier layer, and a wetting layer, and so on. The material can include alloy of aluminum, titanium, tungsten, nickel, gold or copper, being deposited as the composite metallic layer. The conductive bump 222 includes, for example, the tin/lead bump, and can be formed as ball-like bump by reflow process.

In the foregoing embodiment, if the coupling quality between the conductive bump 222 and the protruding pad 214 is in good condition, it can be not necessary to include the complicate fabricating process for the UBM layer 220, so as to reduce the cost of chip fabrication. In addition, the depth of the UBM layer 220 indent into the opening 206 can also be changed by properly setting the height of the protruding pad 214. For example, when the top surface of the protruding pad 214 and the surface of the passivation layer are in the same plane, the conventional structure with step coverage does not occur on the UBM layer 220, and the coverage uniformity of the UBM layer 220 can be improved.

It can be seen that the improved bonding pad structure of the invention is suitable for use in a chip, so as to reduce the electromigration phenomenon due to overlarge turning angle when the current flows through the bonding location between the bonding pad and the UBM layer. Therefore, the improved structure of bonding pad is disposing a protruding pad on the top surface of the bonding pad, the bonding location between the side profile of the protruding pad and the top surface of the bonding pad has a turning angle. The turning angle can be less than 90 degrees or even less than 45 degrees, so that the turning angle, where the current flows, can be subdued, and the phenomenon of overcrowding current can be reduced when the current flows through the turning angle with better smooth path.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

1. A bonding pad structure, suitable for use in a chip, the chip having an active surface, the bonding pad structure comprising:
a bonding pad disposed on the active surface; and
a protruding pad, disposed on the bonding pad and protruded from a top surface of the bonding pad, a turning angle existing at a bonding location between a side profile of the protruding pad and a top surface of the bonding pad, wherein the turning angle is less than 90 degrees for smoothing a current turning path when a current flows through the turning angle.

2. The bonding pad structure of claim 1, wherein the side profile of the protruding pad is a curving surface.

3. The bonding pad structure of claim 1, wherein the side profile of the protruding pad is an arc surface.

4. The bonding pad structure of claim 1, wherein a material of the protruding pad includes copper, aluminum, gold, or alloy thereof.

5. The bonding pad structure of claim 1, wherein the bonding pad includes copper or aluminum.

6. A conductive structure on bonding pad, suitable for use in a chip, the chip having at least a bonding pad, the conductive structure on bonding pad comprising:
a protruding pad, disposed on the bonding pad and protruded from a top surface of the bonding pad, a turning angle existing at a bonding location between a side profile of the protruding pad and a top surface of the bonding pad, wherein the turning angle is less than 90 degrees;
an under bump metallurgic layer, disposed on a surface of the protruding pad farther away from the top surface of the bonding pad; and
a conductive bump, having a bottom connected to a surface of the under bump metallurgic layer.

7. The conductive structure on bonding pad of claim 6, wherein the side profile of the protruding pad is a curving surface.

8. The conductive structure on bonding pad of claim 6, wherein the side profile of the protruding pad is an arc surface.

9. The conductive structure on bonding pad of claim 6, wherein a material of the protruding pad includes copper, aluminum, gold, or alloy thereof.

10. The conductive structure on bonding pad of claim 6, wherein the under bump metallurgic layer includes one selected from the group consisting of aluminum, titanium, tungsten, nickel, gold, copper and alloy thereof.

11. The conductive structure on bonding pad of claim 6, wherein the turning angle is less than 45 degrees.

12. The conductive structure on bonding pad of claim 6, wherein the conductive bump includes alloy of tin and lead.

13. A chip structure, at least comprising
an active surface;
a bonding pad disposed on the active surface;
a protruding pad, disposed on the bonding pad and protruded from a top surface of the bonding pad, a turning angle existing at a bonding location between a side profile of the protruding pad and a top surface of the bonding pad, wherein the turning angle is less than 90 degrees for smoothing a current turning path when a current flows through the turning angle;
a passivation layer disposed on the active surface and encompassing the bonding pad and the protruding pad;
an under bump metallurgic layer, disposed on a surface of the protruding pad farther away from the top surface of the bonding pad and a portion of the passivation layer; and
a conductive bump, having a bottom connected to a surface of the under bump metallurgic layer.

14. The chip structure of claim 13, wherein the side profile of the protruding pad is a curving surface.

15. The chip structure of claim 13, wherein the side profile of the protruding pad is an arc surface.
